(19) United States
(12) Patent Application Publication
(10) Pub. No.: US 2025/0098323 A1
(43) Pub. Date: Mar. 20, 2025

(54) HIGH DENSITY METAL-OXIDE-SEMICONDUCTOR (MOS) CAPACITOR (MOSCAP) AND METAL-OXIDE-METAL (MOM) CAPACITOR (MOMCAP) STACKING LAYOUT

(71) Applicant: QUALCOMM Incorporated, San Diego, CA (US)

(72) Inventors: Ravi Pramod Kumar VEDULA, San Diego, CA (US); Abhijeet PAUL, San Diego, CA (US); Mishel MATLOUBIAN, San Diego, CA (US)

(21) Appl. No.: 18/469,924

(22) Filed: Sep. 19, 2023

(51) Int. Cl. H01L 27/13; H01L 21/84; H01L 23/522

(52) U.S. Cl. CPC H10D 86/80; H01L 23/5223; H10D 86/01

(57) ABSTRACT

An integrated circuit (IC) is described. The IC includes a metal-oxide-metal (MOM) capacitor (MOMCAP). The MOMCAP includes a first terminal coupled to a first plurality of fingers of a first metal interconnect layer. The MOMCAP also includes a second terminal coupled to a second plurality of fingers of the first metal interconnect layer and interdigitated with the first plurality of fingers of the first metal interconnect layer. The IC also includes a first metal-oxide-semiconductor (MOS) capacitor (MOSCAP). The first MOSCAP includes a polysilicon terminal coupled to the first plurality of fingers of the MOMCAP. The first MOSCAP also includes a diffusion terminal coupled to the second plurality of fingers of the MOMCAP.

### BACKGROUND

### Field

Aspects of the present disclosure relate to semiconductor devices and, more particularly, to a high-density metal-oxide-semiconductor (MOS) capacitor (MOSCAP) and a metal-oxide-metal (MOM) capacitor (MOMCAP) stacking layout.

### Background

Mobile radio frequency (RF) chips (e.g., mobile RF transceivers) have migrated to a deep sub-micron process node due to cost and power consumption considerations. Designing mobile RF transceivers is further complicated by added circuit functions for supporting communication enhancements, such as sixth generation (6G) communications systems and fifth generation (5G) new radio (NR) communications systems. Further design challenges for mobile RF transceivers include using passive devices, which directly affect analog/RF performance considerations, including mismatch, noise, and other performance considerations.

Passive devices may involve high performance capacitor components. For example, analog integrated circuits use several types of passive devices, such as integrated capacitors. These integrated capacitors may include metal-oxide-semiconductor (MOS) capacitors (MOSCAPs), p-n junction capacitors, metal-insulator-metal (MIM) capacitors, poly-to-poly capacitors, metal-oxide-metal (MOM) capacitors (MOMCAPs), and other like capacitor structures. MOMCAPs are also known as vertical parallel plate (VPP) capacitors, natural vertical capacitors (NVCAPs), lateral flux capacitors, comb capacitors, as well as interdigitated finger capacitors. Radio frequency (RF) analog (RFA) designs make significant use of capacitors. As a result, increasing capacitance density leads to area reduction and cost savings for RFA designs. An efficient stacking of MOSCAPs with MOMCAPs for an improved RFA design, is desired.

### SUMMARY

An integrated circuit (IC) is described. The IC includes a metal-oxide-metal (MOM) capacitor (MOMCAP). The MOMCAP includes a first terminal coupled to a first plurality of fingers of a first metal interconnect layer. The MOMCAP also includes a second terminal coupled to a second plurality of fingers of the first metal interconnect layer and interdigitated with the first plurality of fingers of the first metal interconnect layer. The IC also includes a first metal-oxide-semiconductor (MOS) capacitor (MOSCAP). The first MOSCAP includes a polysilicon terminal coupled to the first plurality of fingers of the MOMCAP. The first MOSCAP also includes a diffusion terminal coupled to the second plurality of fingers of the MOMCAP.

A method for forming a metal-oxide-semiconductor (MOS) capacitor (MOSCAP) and a metal-oxide-metal (MOM) capacitor (MOMCAP) is described. The method includes forming the MOMCAP. The MOMCAP includes a first terminal coupled to a first plurality of fingers of a first metal interconnect layer. The MOMCAP also includes a second terminal coupled to a second plurality of fingers of the first metal interconnect layer and interdigitated with the first plurality of fingers of the first metal interconnect layer. The method also includes forming a first MOSCAP. The first MOSCAP includes a polysilicon terminal coupled to the first plurality of fingers of the MOMCAP. The first MOSCAP also includes a diffusion terminal coupled to the second plurality of fingers of the MOMCAP.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a schematic diagram of a radio frequency (RF) front end (RFFE) module employing a metal-oxide-metal (MOM) capacitor (MOMCAP) and a metal-oxide-semiconductor (MOS) capacitor (MOSCAP) stacking layout, according to various aspects of the present disclosure.

FIG. 2 is a schematic diagram of a wireless local area network (WLAN) (e.g., Wi-Fi) module including a first diplexer and a radio frequency (RF) front end (RFFE) module including a second diplexer for a chipset, including an optimized high-density metal-oxide-semiconductor (MOS) capacitor (MOSCAP) and a metal-oxide-metal (MOM) capacitor (MOMCAP) stacking layout, according to various aspects of the present disclosure.

FIG. 3 is a block diagram illustrating a cross-section of an analog integrated circuit (IC) device including an interconnect stack that contains conventional metal-oxide-metal (MOM) capacitor (MOMCAP) structures.

FIG. 4 is a schematic layout diagram illustrating a top view of a metal-oxide-metal (MOM) capacitor (MOMCAP) and metal-oxide-semiconductor (MOS) capacitor (MOSCAP) stacking layout, according to various aspects of the present disclosure.

FIG. 5 is a schematic layout diagram illustrating a top view of the metal-oxide-metal (MOM) capacitor (MOMCAP) of FIG. 4 arranged with multiple metal-oxide-semiconductor (MOS) capacitors (MOSCAPs) in a stacking layout, according to various aspects of the present disclosure.

FIGS. 6A-6C are schematic diagrams further illustrating cross-sectional views of the metal-oxide-metal (MOM) capacitor (MOMCAP) and metal-oxide-semiconductor (MOS) capacitor (MOSCAP) stacking layout of FIG. 4, according to various aspects of the present disclosure.

FIG. 7 is a process flow diagram illustrating a method for a metal-oxide-semiconductor (MOS) capacitor (MOSCAP) and a metal-oxide-metal (MOM) capacitor (MOMCAP) stacking layout, according to various aspects of the present disclosure.

FIG. 8 is a block diagram showing an exemplary wireless communications system in which a configuration of the disclosure may be advantageously employed.

FIG. 9 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Mobile radio frequency (RF) chips (e.g., mobile RF transceivers) have migrated to a deep sub-micron process node due to cost and power consumption considerations. Designing mobile RF transceivers is further complicated by added circuit functions for supporting communications enhancements, such as sixth generation (6G) communications systems and fifth generation (5G) new radio (NR) communications systems. Further design challenges for mobile RF transceivers include using passive devices, which directly affect analog/RF performance considerations, including mismatch, noise, and other performance considerations.

Passive devices in mobile RF transceivers may include high performance capacitor components. For example, analog integrated circuits use several types of passive devices, such as integrated capacitors. These integrated capacitors may include metal-oxide-semiconductor (MOS) capacitors (MOSCAPs), p-n junction capacitors, metal-insulator-metal (MIM) capacitors, poly-to-poly capacitors, metal-oxide-metal (MOM) capacitors (MOMCAPs), and other like capacitor structures. Capacitors are passive elements used in integrated circuits for storing an electrical charge. For example, parallel plate capacitors are often made using plates or structures that are conductive with an insulating material between the plates. The amount of storage, or capacitance, for a given capacitor is contingent upon the materials used to make the plates and the insulator, the area of the plates, and the spacing between the plates. The insulating material is often a dielectric material.

These parallel plate capacitors consume a large area on a semiconductor chip because many designs place the capacitor over the substrate of the chip. Unfortunately, this approach reduces the available area for active devices. Another approach is to create a vertical structure, which may be known as a vertical parallel plate (VPP) capacitor. VPP capacitor structures may be created through stacking of the interconnect layers on a chip.

VPP capacitor structures, however, have lower capacitive storage, or lower “density,” in that these structures do not store much electrical charge. In particular, the interconnect and via layer interconnect traces to fabricate VPP capacitors may be exceedingly small in size. The spacing between the interconnects and via layer conductive traces in VPP structures is limited by design rules, which often results in a large area for achieving certain desired capacitance for such structures. Although described as “vertical,” these structures can be oriented in any direction that is perpendicular to the surface of the substrate, or at other angles that are not parallel to the substrate.

A MOMCAP as well as a MOSCAP are examples of VPP capacitors. MOMCAPs are one of the most widely used capacitors due to their beneficial characteristics. In particular, MOMCAPs may provide high quality capacitors in semiconductor processes without incurring the cost of an extra processing step relative to other capacitor structures. MOMCAP structures realize capacitance by using the fringing capacitance produced by sets of interdigitated fingers. That is, MOMCAPs harness lateral capacitive coupling between plates formed by metallization layers and wiring traces.

Radio frequency (RF) analog (RFA) designs make significant use of capacitors. As a result, increasing capacitance density leads to area reduction and cost savings for RFA designs. Unfortunately, current stacking of MOMCAP layouts are inefficient and MOSCAP layouts may occupy between 15% and 20% of a chip area for a product. Hence, stacking of MOSCAPs with MOMCAP layouts is not widely used, especially in cost sensitive technologies with limited metal layers. Consequently, an efficient stacking of MOSCAPs with MOMCAP layouts for an improved RFA design, is desired.

Various aspects of the present disclosure provide an optimized high-density metal-oxide-semiconductor (MOS) capacitor (MOSCAP) and metal-oxide-metal (MOM) capacitor (MOMCAP) stacking layout. The process flow for fabrication of the capacitor array and inductor may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

As described, the BEOL interconnect layers may refer to the conductive interconnect layers (e.g., a first interconnect layer (M1) or metal one M1, metal two (M2), metal three (M3), metal four (M4), etc.) for electrically coupling to FEOL active devices of an integrated circuit. The various BEOL interconnect layers are formed at corresponding BEOL interconnect levels, in which lower BEOL interconnect levels use thinner metals layers relative to upper BEOL interconnect levels. The BEOL interconnect layers may electrically couple to MOL interconnect layers, for example, to connect M1 to an oxide diffusion (OD) layer of an integrated circuit. The middle-of-line interconnect layer may include a zero-interconnect layer (M0) for connecting M1 to an active device layer of an integrated circuit. A BEOL first via (V2) may connect M2 to M3 or others of the BEOL interconnect layers.

According to various aspects of the present disclosure, an optimized high-density metal-oxide-semiconductor (MOS) capacitor (MOSCAP) and metal-oxide-metal (MOM) capacitor (MOMCAP) stacking layout is described. The capacitor stacking layout includes a MOMCAP composed of a first terminal coupled to a first set of fingers. The MOMCAP also includes a second terminal coupled to a second set of fingers composed of a first metal layer interconnect and interdigitated with the first set of fingers composed of the first metal layer interconnect. The capacitor stacking layout also includes a MOSCAP composed of a polysilicon region coupled to the first set of the fingers of the first terminal. The MOSCAP includes a diffusion region coupled to the second set of fingers.

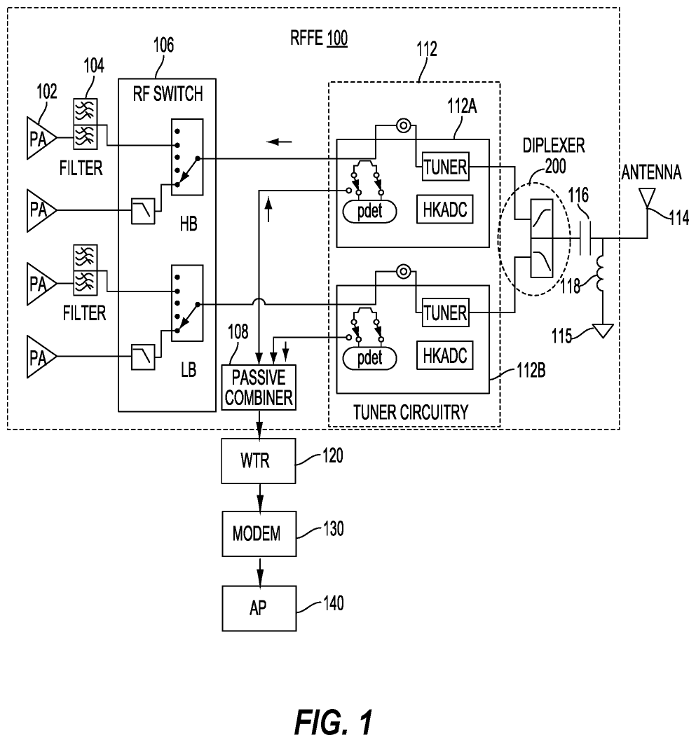

FIG. 1 is a schematic diagram of a radio frequency (RF) front end (RFFE) module 100 employing passive devices including a capacitor 116 (e.g., an optimized high-density metal-oxide-semiconductor (MOS) capacitor (MOSCAP) and metal-oxide-metal (MOM) capacitor (MOMCAP) stacking layout). The RFFE module 100 includes power amplifiers 102, duplexer/filters 104, and an RF switch module 106. The power amplifiers 102 amplify signal(s) to a certain power level for transmission. The duplexer/filters 104 filter the input/output signals according to a variety of different parameters, including frequency, insertion loss, rejection, or other like parameters. In addition, the RF switch module 106 may select certain portions of the input signals to pass on to the rest of the RFFE module 100.

The RFFE module 100 also includes tuner circuitry 112 (e.g., first tuner circuitry 112A and second tuner circuitry 112B), the diplexer 200, a capacitor 116, an inductor 118, a ground terminal 115, and an antenna 114. The tuner circuitry 112 (e.g., the first tuner circuitry 112A and the second tuner circuitry 112B) includes components such as a tuner, a portable data entry terminal (PDET), and a house keeping analog to digital converter (HKADC). The tuner circuitry 112 may perform impedance tuning (e.g., a voltage standing wave ratio (VSWR) optimization) for the antenna 114. The RFFE module 100 also includes a passive combiner 108 coupled to a wireless transceiver (WTR) 120. The passive combiner 108 combines the detected power from the first tuner circuitry 112A and the second tuner circuitry 112B. The wireless transceiver 120 processes the information from the passive combiner 108 and provides this information to a modem 130 (e.g., a mobile station modem (MSM)). The modem 130 provides a digital signal to an application processor (AP) 140.

As shown in FIG. 1, the diplexer 200 is between the tuner component of the tuner circuitry 112 and the capacitor 116, the inductor 118, and the antenna 114. The diplexer 200 may be placed between the antenna 114 and the tuner circuitry 112 to provide high system performance from the RFFE module 100 to a chipset including the WTR 120, the modem 130, and the application processor 140. The diplexer 200 also performs frequency domain multiplexing on both high band frequencies and low band frequencies. After the diplexer 200 performs its frequency multiplexing functions on the input signals, the output of the diplexer 200 is fed to an optional inductor/capacitor (LC) network including the capacitor 116 and the inductor 118. The LC network may provide extra impedance matching components for the antenna 114, when desired. Then, a signal with the particular frequency is transmitted or received by the antenna 114. Although a single capacitor and inductor are shown, multiple components are also contemplated.

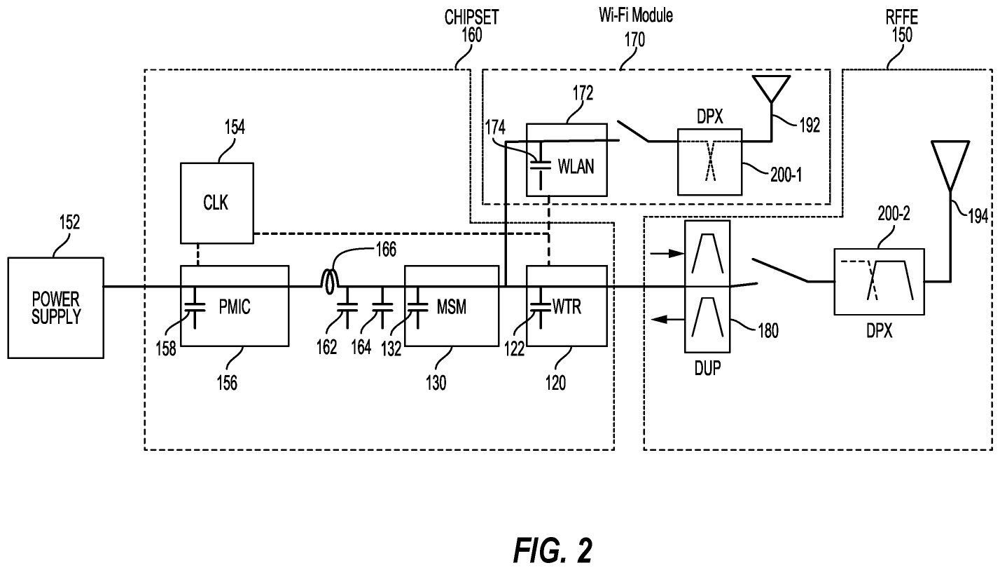

FIG. 2 is a schematic diagram of a wireless local area network (WLAN) (e.g., Wi-Fi) module 170 including a first diplexer 200-1 and a radio frequency (RF) front end (RFFE) module 150 including a second diplexer 200-2 for a chipset 160, including an optimized high-density metal-oxide-semiconductor (MOS) capacitor (MOSCAP) and a metal-oxide-metal (MOM) capacitor (MOMCAP) stacking layout, according to various aspects of the present disclosure. The Wi-Fi module 170 includes the first diplexer 200-1 communicably coupling an antenna 192 to a WLAN module (e.g., WLAN module 172). The RFFE module 150 includes the second diplexer 200-2 communicably coupling an antenna 194 to the wireless transceiver (WTR) 120 through a duplexer 180. The WTR 120 and the WLAN module 172 of the Wi-Fi module 170 are coupled to a modem (MSM, e.g., baseband modem) 130 that is powered by a power supply 152 through a power management integrated circuit (PMIC) 156. The chipset 160 also includes capacitors 162 and 164, as well as an inductor(s) 166 to provide signal integrity.

The PMIC 156, the MSM 130, the WTR 120, and the WLAN module 172 each include capacitors (e.g., 158, 132, 122, and 174) and operate according to a clock 154. In addition, the inductor 166 couples the MSM 130 to the PMIC 156. The geometry and arrangement of the various capacitors and inductors in the chipset 160 may consume substantial chip area. The design of the chipset 160 includes significant use of capacitors. As a result, increasing capacitance density leads to area reduction and cost savings for design of the chipset 160. Unfortunately, current stacking of MOMCAP layouts are inefficient and MOSCAP layouts may occupy between 15% and 20% of a chip area for a typical product. Hence, stacking of MOSCAPs with MOMCAP layouts is not widely used, especially in cost sensitive technologies with limited metal layers. Consequently, an efficient stacking of MOSCAPs with MOMCAP layouts for an improved radio frequency analog (RFA) design, is desired.

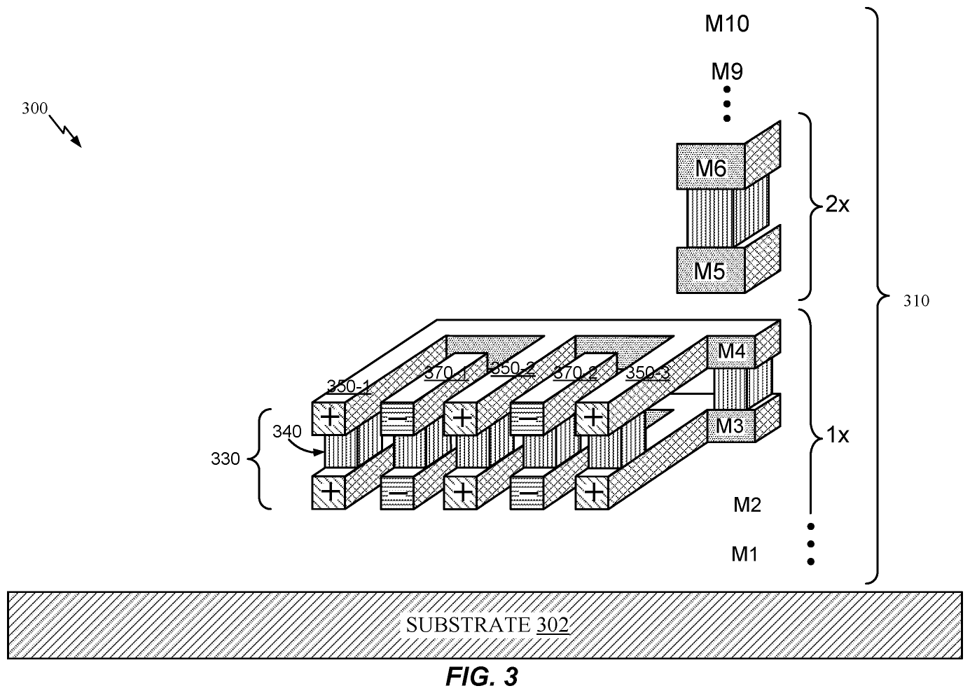

Capacitors are widely used in analog integrated circuits. FIG. 3 is a block diagram illustrating a cross-section of an analog integrated circuit (IC) device 300 including an interconnect stack 310. The interconnect stack 310 of the IC device 300 includes multiple conductive interconnect layers (M1, . . . , M9, M10) on a semiconductor substrate (e.g., a diced silicon wafer) 302. The semiconductor substrate 302 supports a metal-oxide-metal (MOM) capacitor (MOMCAP) 330 and/or a metal-oxide-semiconductor (MOS) capacitor (MOSCAP). In this example, the MOMCAP 330 is formed in the M3 and M4 interconnect layers, below the M5 and M6 interconnect layers. The MOMCAP 330 is formed from lateral conductive fingers of different polarities using the conductive interconnect layers (M3 and M4) of the interconnect stack 310. A dielectric (not shown) is provided between the conductive fingers.

In this example, the MOMCAP 330 is formed within the lower conductive interconnect layers (e.g., M1-M4) of the interconnect stack 310. The lower conductive interconnect layers of the interconnect stack 310 have smaller interconnect widths and spaces. For example, the dimensions of the conductive interconnect layers M3 and M4 are half the size of the dimensions of the conductive interconnect layers M5 and M6. Likewise, the dimensions of the conductive interconnect layers M1 and M2 are half the size of the dimensions of the conductive interconnect layers M3 and M4. The small interconnect widths and spaces of the lower conductive interconnect layers enable the formation of MOMCAPs with increased capacitance density.

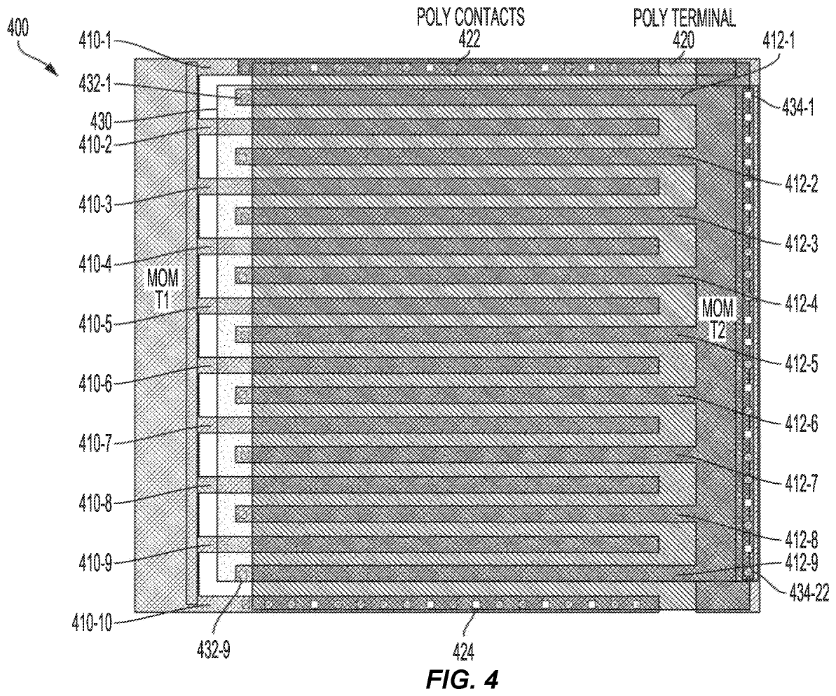

As shown in FIG. 3, the MOMCAP 330 makes use of a lateral (intra layer) capacitive coupling 340 between fingers (e.g., 350, 370) formed by standard metallization of the conductive interconnects (e.g., wiring lines and vias). In various aspects of the present disclosure, an optimized high density MOSCAP and a MOMCAP stacking layout is provided, for example, as shown in FIG. 4.

FIG. 4 is a schematic layout diagram illustrating a top view of a metal-oxide-metal (MOM) capacitor (MOMCAP) and metal-oxide-semiconductor (MOS) capacitor (MOSCAP) stacking layout, according to various aspects of the present disclosure. As shown in FIG. 4, a MOSCAP and MOMCAP stacking layout 400 includes a metal-oxide-metal (MOM) capacitor (MOMCAP) composed of a first (T1) terminal coupled to a first set of fingers 410 (410-1, 410-2, . . . , 410-10). The MOMCAP also includes a second (T2) terminal coupled to a second set of fingers 412 (412-1, 412-2, . . . , 412-9), composed of a first metal layer (M1) interconnect and interdigitated with the first set of fingers 410 composed of the M1 interconnect. The MOSCAP and MOMCAP stacking layout 400 also includes a metal-oxide-semiconductor (MOS) capacitor (MOSCAP) composed of a poly terminal 420 coupled to the first set of fingers 410 of the T1 terminal. The MOSCAP includes a diffusion terminal 430 coupled to the second set of fingers 412 of the T2 terminal of the MOMCAP.

In aspects of the present disclosure, outer ones (e.g., 410-1 and 410-10) of the first set of fingers 410 of the T1 terminal are coupled to the poly terminal 420. As shown in FIG. 4, a first outer finger 410-1 is coupled to the poly terminal 420 through a first set of metal to poly (MP) contacts 422, and a tenth outer finger 410-10 is coupled to the poly terminal 420 through a second set of metal to poly (MP) contacts 424. Additionally, the diffusion terminal 430 is coupled to the second set of fingers 412 and the T2 terminal. As shown in FIG. 4, a first set of metal to diffusion (MD) contacts 432 (432-1, . . . , 432-9) couples the diffusion terminal 430 to ends of the second set of fingers 412, distal from the T2 terminal. Additionally, a second set of metal to diffusion (MD) contacts 434 (434-1, . . . , 434-22) couples the diffusion terminal 430 to an end of the T2 terminal.

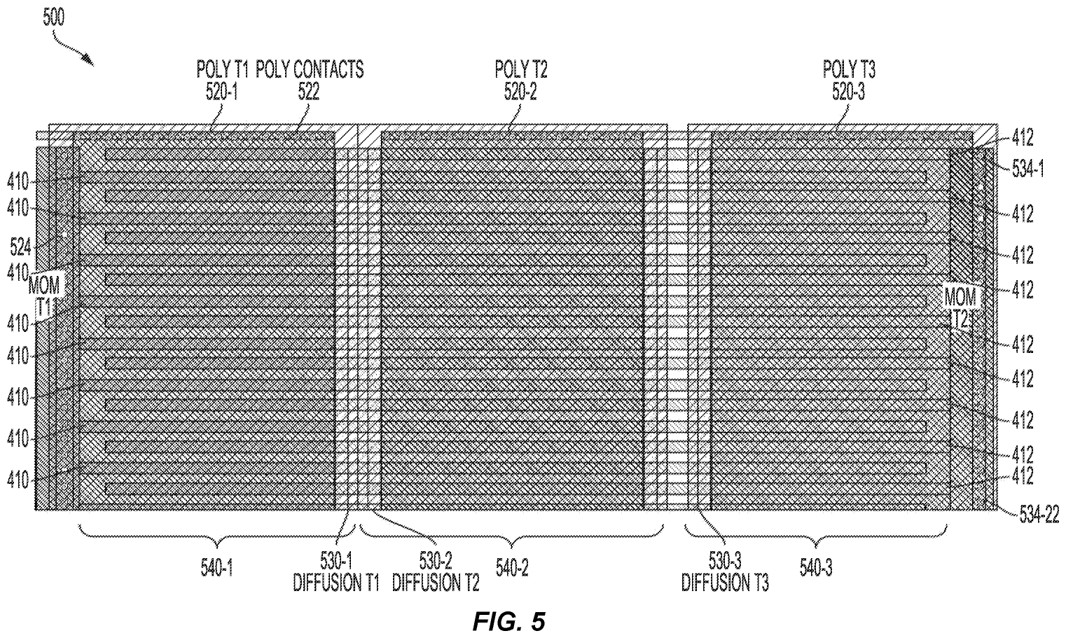

FIG. 5 is a schematic layout diagram illustrating a top view of the metal-oxide-metal (MOM) capacitor (MOMCAP) of FIG. 4 arranged with multiple metal-oxide-semiconductor (MOS) capacitors (MOSCAPs) in a stacking layout, according to various aspects of the present disclosure. As shown in FIG. 5, a capacitor stacking layout 500 illustrates the MOMCAP of FIG. 4 arranged with multiple, stacked MOSCAPs 540 (540-1, 540-2, 540-3) to support high voltage (e.g., six-volt (6 V)) applications. In this example, a first poly terminal 520-1 of a first MOSCAP 540-1 is coupled to the T1 terminal of the MOMCAP through first poly contacts 522. Additionally, the first poly terminal 520-1 of the first MOSCAP 540-1 is alternatively coupled to the T1 terminal of the MOMCAP through second poly contacts 524.

In these aspects of the present disclosure, a first diffusion terminal 530-1 of the first MOSCAP 540-1 is shorted to a second diffusion terminal 530-2 of a second MOSCAP 540-2. Additionally, a second poly terminal 520-2 of the second MOSCAP 540-2 is shorted to a third poly terminal 520-3 of a third MOSCAP 540-3. In various aspects of the present disclosure, a third diffusion terminal 530-3 of the third MOSCAP 540-3 is coupled to the T3 terminal of the third MOSCAP 540-3 through diffusion contacts 534 (534-1, . . . , 534-22). In various aspects of the present disclosure, stacking of the MOSCAPs 540 in the capacitor stacking layout 500 of FIG. 5 beneficially supports higher voltage applications (e.g., 6 V applications) relative to lower voltage applications (e.g., 2.5 V). In this example, a capacitance density of the stacked MOMCAPs in the capacitor stacking layout 500 is from 1.6 fempto farads (fF)/microns², accounting for the space lost from receiver (RX) separation.

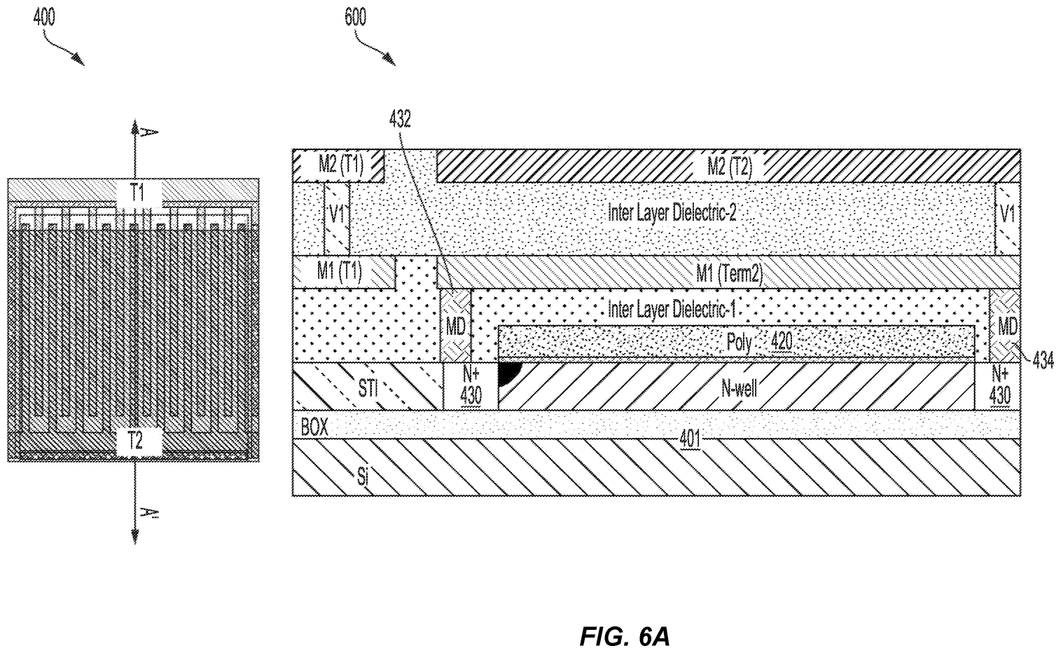

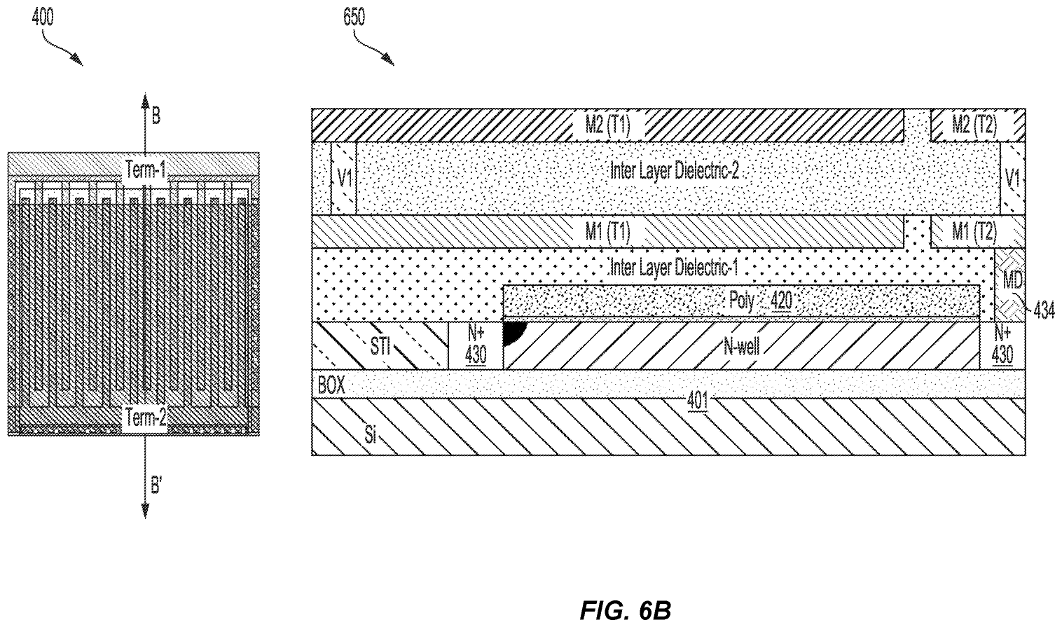

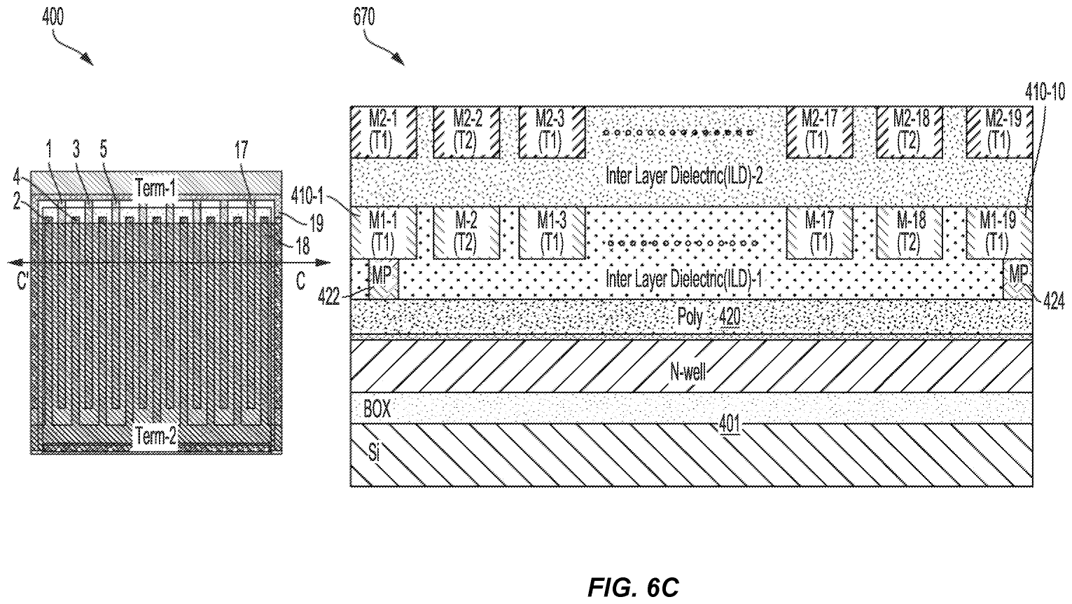

FIGS. 6A-6C are schematic diagrams further illustrating cross-sectional views of the metal-oxide-metal (MOM) capacitor (MOMCAP) and the metal-oxide-semiconductor (MOS) capacitor (MOSCAP) stacking layout of FIG. 4, according to various aspects of the present disclosure.

FIG. 6A illustrates a cross-section view 600 of the MOSCAP and MOMCAP stacking layout 400 of FIG. 4 also a cutline AA′, according to various aspects of the present disclosure. As shown in the cross-section view 600, the MOSCAP and MOMCAP stacking layout 400 includes a semiconductor-on-insulator (SOI) substrate 401, supporting an N-type well (N-well), N+ diffusion regions (e.g., source/drain regions), and a shallow trench isolation (STI) region of a MOSCAP. The MOSCAP also includes the poly terminal 420 on an oxide on the N-well to provide the poly terminal 420 of the MOSCAP as well as N+ diffusion regions to provide the diffusion terminal 430 of the MOSCAP of the MOSCAP and MOMCAP stacking layout 400. Additionally, the MOMCAP is shown to include an M1 T1 terminal and an M1 T2 terminal coupled to the diffusion terminal 430 through metal to diffusion (MD) contacts 432 and 434 through a first interlayer dielectric (ILD). In this example, an M2 T1 terminal is coupled to the T1 terminal through a first BEOL via V1 in a second ILD and an M2 T2 terminal is coupled to the M1 T2 terminal through a first BEOL via V1 in the second ILD.

FIG. 6B illustrates a cross-section view 650 of the MOSCAP and MOMCAP stacking layout 400 of FIG. 4 along a cutline BB′, according to various aspects of the present disclosure. As shown in the cross-section view 650, the MOMCAP is shown to include an M1 T1 terminal that is not coupled to the diffusion terminal 430, and an M1 T2 terminal coupled to the diffusion terminal through the MD contact 434 through the first ILD. Additionally, the M2 T1 terminal is coupled to the M1 T1 terminal through a via V1 in the second ILD, and the M2 T2 terminal is coupled to the M1 T1 terminal through a via V1 in the second ILD.

FIG. 6C illustrates a cross-section view 670 of the MOSCAP and MOMCAP stacking layout 400 of FIG. 4 along a cutline CC′, according to various aspects of the present disclosure. As shown in the cross-section view 670, the MOMCAP is shown with outer ones (e.g., 1 and 19) of the first set of fingers of the T1 terminal coupled to the poly terminal 420 thought metal to poly (MP) contacts 422 and 424. Additionally, the M2 T1 terminals (e.g., M2-1, M2-3, . . . , M2-19) and the M2 T2 terminals (e.g., M2-2, M2-4, . . . , M2-18) are shown. A connection between the M2 T1 and T2 terminals and the M1 T1 and T2 terminal is not shown.

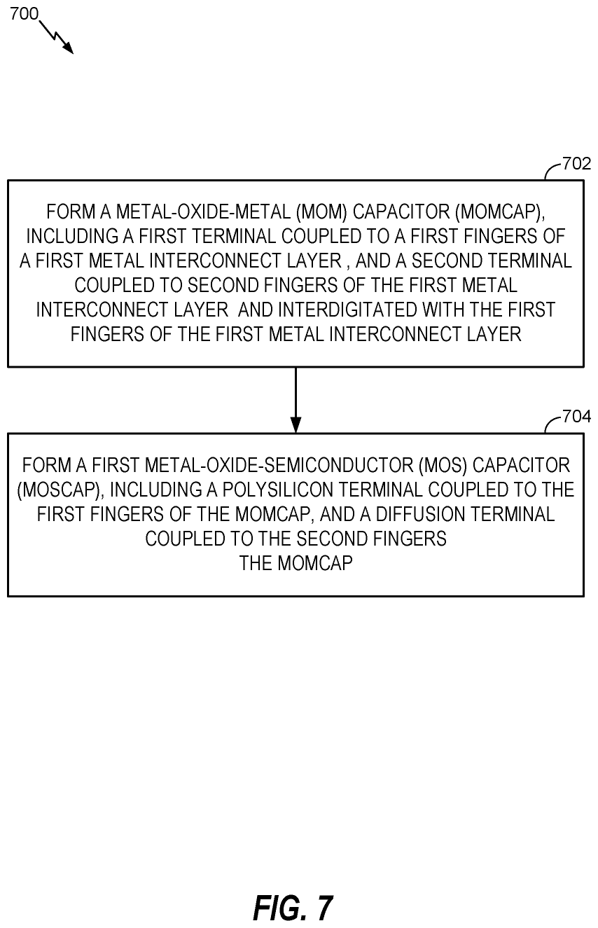

FIG. 7 is a process flow diagram illustrating a method 700 for forming a metal-oxide-semiconductor (MOS) capacitor (MOSCAP) and a metal-oxide-metal (MOM) capacitor (MOMCAP), according to various aspects of the present disclosure. A method 700 begins at block 702, in which a MOMCAP is formed, including a first terminal coupled to a first fingers of a first metal interconnect layer, and a second terminal coupled to second fingers of the first metal interconnect layer and interdigitated with the first fingers of the first metal interconnect layer. For example, as shown in FIG. 4, the MOMCAP is composed of a first (T1) terminal coupled to a first set of fingers 410 (410-1, 410-2, . . . , 410-10). The MOMCAP also includes a second (T2) terminal coupled to a second set of fingers 412 (412-1, 412-2, . . . , 412-9), composed of a first metal layer (M1) interconnect and interdigitated with the first set of fingers 410 composed of the M1 interconnect.

At block 740, a first MOSCAP is formed, including a polysilicon terminal coupled to the first fingers of the first terminal of the MOMCAP, and a diffusion terminal coupled to the second fingers of the second terminal of the MOMCAP. For example, as shown in FIG. 4, the MOSCAP and MOMCAP stacking layout 400 also includes the MOSCAP, composed of a poly terminal 420 coupled to the first set of fingers 410 of the T1 terminal. The MOSCAP includes a diffusion terminal 430 coupled to the second set of fingers 412 of the T2 terminal of the MOMCAP.

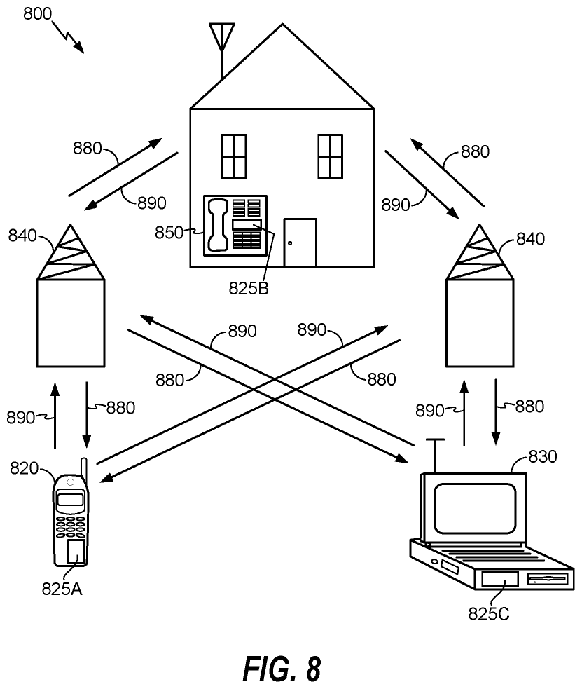

FIG. 8 is a block diagram showing an exemplary wireless communication system 800 in which an aspect of the disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825C, and 825B that include the disclosed capacitor stacking layout. It will be recognized that other devices may also include the disclosed capacitor stacking layout, such as the base stations, switching devices, and network equipment. FIG. 8 shows forward link signals 880 from the base station 840 to the remote units 820, 830, and 850 and reverse link signals 890 from the remote units 820, 830, and 850 to base stations 840.

In FIG. 8, remote unit 820 is shown as a mobile telephone, remote unit 830 is shown as a portable computer, and remote unit 850 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as a meter reading equipment, or other device that stores or retrieves data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the disclosed capacitor stacking layout.

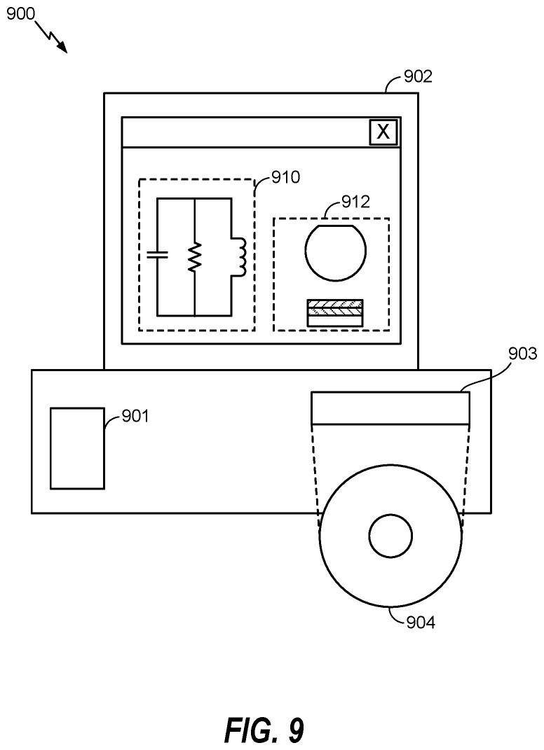

FIG. 9 is a block diagram illustrating a design workstation used for circuit, layout, and logic design of a semiconductor component, such as the capacitors disclosed above. A design workstation 900 includes a hard disk 901 containing operating system software, support files, and design software such as Cadence or OrCAD. The design workstation 900 also includes a display 902 to facilitate design of a circuit 910 or an RF component 912 such as a capacitor stacking layout. A storage medium 904 is provided for tangibly storing the design of the circuit 910 or the RF component 912 (e.g., the disclosed capacitor stacking layout). The design of the circuit 910 or the RF component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the RF component 912 (e.g., the disclosed capacitor stacking layout) by decreasing the number of processes for designing semiconductor wafers.

Implementation examples are described in the following numbered clauses:

1. An integrated circuit (IC), comprising:
a metal-oxide-metal (MOM) capacitor (MOMCAP), comprising:
   a first terminal coupled to a first plurality of fingers of a first metal interconnect layer, and
   a second terminal coupled to a second plurality of fingers of the first metal interconnect layer and interdigitated with the first plurality of fingers of the first metal interconnect layer; and
a first metal-oxide-semiconductor (MOS) capacitor (MOSCAP) comprising:
   a polysilicon terminal coupled to the first plurality of fingers of the MOMCAP, and
   a diffusion terminal coupled to the second plurality of fingers of the MOMCAP.

2. The IC of clause 1, in which outer ones of the first plurality of fingers are coupled to the polysilicon terminal through a plurality of polysilicon contacts.

3. The IC of any of clauses 1 or 2, in which the diffusion terminal is coupled to the second terminal through a plurality of diffusion contacts.

4. The IC of any of clauses 1-3, in which the diffusion terminal is coupled to ends of the second plurality of fingers, distal from the second terminal through a plurality of diffusion contacts.

5. The IC of any of clauses 1-4, further comprising:
a second MOSCAP coupled to the first MOSCAP; and
a third MOSCAP coupled to the second MOSCAP.

6. The IC of clause 5, in which a second diffusion terminal of the second MOSCAP is shorted to the diffusion terminal of the first MOSCAP.

7. The IC of any of clauses 5 or 6, in which a second poly terminal of the second MOSCAP is shorted to a third poly terminal of the third MOSCAP.

8. The IC of any of clauses 5-7, in which a third diffusion terminal of the third MOSCAP is coupled to the second terminal of the MOMCAP.

9. The IC of any of clauses 1-8, integrated in a radio frequency (RF) front-end (RFFE) module.

10. The IC of clause 9, in which the RFFE module is integrated in a mobile phone, a set top box, a music player, a video player, an entertainment unit, a navigation device, a computer, a hand-held personal communication systems (PCS) unit, a portable data unit, and/or a fixed location data unit.

11. A method for forming a metal-oxide-semiconductor (MOS) capacitor (MOSCAP) and a metal-oxide-metal (MOM) capacitor (MOMCAP), the method comprising:
forming the MOMCAP, comprising:
   a first terminal coupled to a first plurality of fingers of a first metal interconnect layer, and
   a second terminal coupled to a second plurality of fingers of the first metal interconnect layer and interdigitated with the first plurality of fingers of the first metal interconnect layer; and
forming a first MOSCAP, comprising:
   a polysilicon terminal coupled to the first plurality of fingers of the MOMCAP, and
   a diffusion terminal coupled to the second plurality of fingers of the MOMCAP.

12. The method of clause 11, in which outer ones of the first plurality of fingers are coupled to the polysilicon terminal through a plurality of polysilicon contacts.

13. The method of any of clauses 11 or 12, in which the diffusion terminal is coupled to the second terminal through a plurality of diffusion contacts.

14. The method of any of clauses 11-13, in which the diffusion terminal is coupled to ends of the second plurality of fingers, distal from the second terminal through a plurality of diffusion contacts.

15. The method of any of clauses 11-14, further comprising:
forming a second MOSCAP coupled to the first MOSCAP; and
forming a third MOSCAP coupled to the second MOSCAP.

16. The method of clause 15, in which a second diffusion terminal of the second MOSCAP is shorted to the diffusion terminal of the first MOSCAP.

17. The method of any of clauses 15 or 16, in which a second poly terminal of the second MOSCAP is shorted to a third poly terminal of the third MOSCAP.

18. The method of any of clauses 15-17, in which a third diffusion terminal of the third MOSCAP is coupled to the second terminal of the MOMCAP.

19. The method of any of clauses 11-18, further comprising integrating the first MOSCAP and the MOMCAP in a radio frequency (RF) front-end (RFFE) module.

20. The method of clause 19, further comprising integrating the RFFE module in a mobile phone, a set top box, a music player, a video player, an entertainment unit, a navigation device, a computer, a hand-held personal communication systems (PCS) unit, a portable data unit, and/or a fixed location data unit.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC), comprising:
a metal-oxide-metal (MOM) capacitor (MOMCAP), comprising:
a first terminal coupled to a first plurality of fingers of a first metal interconnect layer, and
a second terminal coupled to a second plurality of fingers of the first metal interconnect layer and interdigitated with the first plurality of fingers of the first metal interconnect layer; and
a first metal-oxide-semiconductor (MOS) capacitor (MOSCAP) comprising:
a polysilicon terminal coupled to the first plurality of fingers of the MOMCAP, and
a diffusion terminal coupled to the second plurality of fingers of the MOMCAP.

2. The IC of claim 1, in which outer ones of the first plurality of fingers are coupled to the polysilicon terminal through a plurality of polysilicon contacts.

3. The IC of claim 1, in which the diffusion terminal is coupled to the second terminal through a plurality of diffusion contacts.

4. The IC of claim 1, in which the diffusion terminal is coupled to ends of the second plurality of fingers, distal from the second terminal through a plurality of diffusion contacts.

5. The IC of claim 1, further comprising:
a second MOSCAP coupled to the first MOSCAP; and
a third MOSCAP coupled to the second MOSCAP.

6. The IC of claim 5, in which a second diffusion terminal of the second MOSCAP is shorted to the diffusion terminal of the first MOSCAP.

7. The IC of claim 5, in which a second poly terminal of the second MOSCAP is shorted to a third poly terminal of the third MOSCAP.

8. The IC of claim 5, in which a third diffusion terminal of the third MOSCAP is coupled to the second terminal of the MOMCAP.

9. The IC of claim 1, integrated in a radio frequency (RF) front-end (RFFE) module.

10. The IC of claim 9, in which the RFFE module is integrated in a mobile phone, a set top box, a music player, a video player, an entertainment unit, a navigation device, a computer, a hand-held personal communication systems (PCS) unit, a portable data unit, and/or a fixed location data unit.

11. A method for forming a metal-oxide-semiconductor (MOS) capacitor (MOSCAP) and a metal-oxide-metal (MOM) capacitor (MOMCAP), the method comprising:
forming the MOMCAP, comprising:
a first terminal coupled to a first plurality of fingers of a first metal interconnect layer, and
a second terminal coupled to a second plurality of fingers of the first metal interconnect layer and interdigitated with the first plurality of fingers of the first metal interconnect layer; and
forming a first MOSCAP, comprising:
a polysilicon terminal coupled to the first plurality of fingers of the MOMCAP, and
a diffusion terminal coupled to the second plurality of fingers of the MOMCAP.

12. The method of claim 11, in which outer ones of the first plurality of fingers are coupled to the polysilicon terminal through a plurality of polysilicon contacts.

13. The method of claim 11, in which the diffusion terminal is coupled to the second terminal through a plurality of diffusion contacts.

14. The method of claim 11, in which the diffusion terminal is coupled to ends of the second plurality of fingers, distal from the second terminal through a plurality of diffusion contacts.

15. The method of claim 11, further comprising:
forming a second MOSCAP coupled to the first MOSCAP; and
forming a third MOSCAP coupled to the second MOSCAP.

16. The method of claim 15, in which a second diffusion terminal of the second MOSCAP is shorted to the diffusion terminal of the first MOSCAP.

17. The method of claim 15, in which a second poly terminal of the second MOSCAP is shorted to a third poly terminal of the third MOSCAP.

18. The method of claim 15, in which a third diffusion terminal of the third MOSCAP is coupled to the second terminal of the MOMCAP.

19. The method of claim 11, further comprising integrating the first MOSCAP and the MOMCAP in a radio frequency (RF) front-end (RFFE) module.

20. The method of claim 19, further comprising integrating the RFFE module in a mobile phone, a set top box, a music player, a video player, an entertainment unit, a navigation device, a computer, a hand-held personal communication systems (PCS) unit, a portable data unit, and/or a fixed location data unit.
